(19) United States
(12) Patent Application Publication
(10) Pub. No.: US 2004/0211881 A1
(43) Pub. Date: Oct. 28, 2004

(54) Image sensor capable of avoiding lateral light interference

(76) Inventor: Pierre Liu, Hsinchu Hsien (TW)

Correspondence Address: PRO-TECHTOR INTERNATIONAL, 20775 Norada Court, Saratoga, CA, 95070-3018, US

(21) Appl. No.: 10/422,197

(22) Filed: Apr. 23, 2003

(51) Int. Cl. H01L 27/00

(52) U.S. Cl. 250/208.1

(57) ABSTRACT

An image sensor of the invention includes a substrate, a photosensitive chip, and a transparent layer. The substrate has an upper surface and a lower surface. The photosensitive chip is mounted to the upper surface of the substrate and is electrically connected to the substrate. The transparent layer has a [symbol] -shaped structure including a frame and a cover on the frame. The frame is adhered to the upper surface of the substrate to cover the photosensitive chip so that the photosensitive chip may receive image signals passing through the cover of the transparent layer. The frame is also formed with a protection layer at a periphery thereof so as to avoid lateral light interference.

### BACKGROUND OF THE INVENTION

1. Field of the Invention

The invention relates to an image sensor capable of avoiding lateral light interference, and in particular to an image sensor with enhanced sensor effects.

2. Description of the Related Art

A general sensor is used to sense signals, which may be optical or audio signals. The sensor of the invention is used to receive image signals or optical signals. After receiving the image signals, the sensor converts the image signals into electrical signals, which are then transmitted to a printed circuit board via a substrate.

Referring to FIG. 1, a conventional image sensor includes a substrate 10, a photosensitive chip 20, and a transparent layer 24. The substrate 10 has a first surface 12 on which signal input terminals 16 are formed and a second surface 14 on which signal output terminals 18 are formed. The photosensitive chip 20 is mounted to the first surface 12 of the substrate 10 and is electrically connected to the substrate 10. The transparent layer 24 is adhered to the first surface 12 of the substrate 10, and a cavity 26 is formed in the central portion of the transparent layer 24. The photosensitive chip 20 mounted to the substrate 10 is arranged within the cavity 26 of the transparent layer 24 so that the photosensitive chip 20 may receive optical signals passing through the transparent layer 24.

The conventional image sensor has the following drawbacks.

Since the transparent layer is a piece of transparent glass or transparent glue, light rays may enter the cavity 26 from anywhere and interference with the image signal reception of the photosensitive chip 20.

### SUMMARY OF THE INVENTION

An object of the invention is to provide an image sensor capable of avoiding lateral light interference.

To achieve the above-mentioned object, the invention provides an image sensor including a substrate, a photosensitive chip, and a transparent layer. The substrate has an upper surface and a lower surface. The photosensitive chip is mounted to the upper surface of the substrate and is electrically connected to the substrate. The transparent layer has a [symbol] -shaped structure including a frame and a cover on the frame. The frame is adhered to the upper surface of the substrate to cover the photosensitive chip so that the photosensitive chip may receive image signals passing through the cover of the transparent layer. The frame is also formed with a protection layer at a periphery thereof so as to avoid lateral light interference.

### BRIEF DESCRIPTION OF THE DRAWINGS

FIG. 1 is a schematic illustration showing a conventional image sensor disclosed in U.S. patent application Ser. No. 09/770,051, which is assigned to the same assignee as this application.

FIG. 2 is a cross-sectional view showing an image sensor capable of avoiding lateral light interference according to an embodiment of the invention.

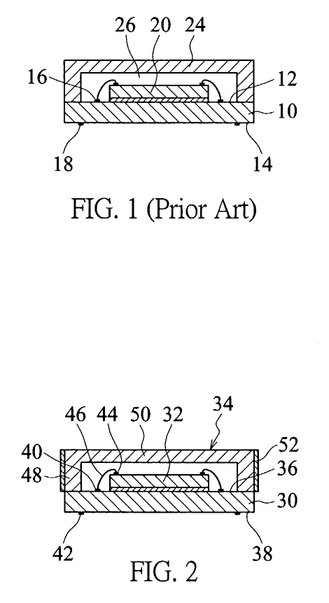

### DETAILED DESCRIPTION OF THE INVENTION

Referring to FIG. 2, an image sensor of the invention includes a substrate 30, a photosensitive chip 32, and a transparent layer 34.

The substrate 30 has an upper surface 36 formed with a plurality of first connection points 40 and a lower surface 38 formed with a plurality of second connection points 42.

The photosensitive chip 32 is formed with a plurality of bonding pads 44 and is mounted to the upper surface 36 of the substrate 30. The wires 46 electrically connect the bonding pads 44 to the first connection points 40, respectively, so that signals from the photosensitive chip 32 may be transferred to the substrate 30.

The transparent layer 34 is a piece of transparent glass or transparent glue and has an integrally formed [symbol] -shaped structure including a frame 48 and a cover 50 on a top of the frame 48. The frame 48 is adhered to the upper surface 36 of the substrate 30 to cover the photosensitive chip 32 so that the photosensitive chip 32 may receive image signals passing through the cover 50 of the transparent layer 34. A periphery of the frame 48 is blurred to form a protection layer 52 so as to avoid lateral light interference.

The image sensor of the invention has the following advantages.

1. Since the wires 46 are first bonded to the upper surface 36 of the substrate 30 and then the transparent layer 34 is placed on the substrate 30, the wire bonding process may be conveniently performed.

2 The protection layer 52 formed on the periphery of the frame 48 of the transparent layer 34 may avoid the influence of the lateral light interference on the signal reception of the photosensitive chip 32.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. An image sensor capable of avoiding lateral light interference, comprising:
a substrate having an upper surface formed with a plurality of first connection points and a lower surface formed with a plurality of second connection points;
a photosensitive chip mounted to the upper surface of the substrate and electrically connected to the plurality of first connection points; and
a transparent layer having a [symbol] -shaped structure including a frame and a cover on the frame, the frame being adhered to the upper surface of the substrate to cover the photosensitive chip so that the photosensitive chip may receive image signals passing through the cover of the transparent layer, and the frame being formed with a protection layer at a periphery thereof so as to avoid lateral light interference.

2. The image sensor according to claim 1, further comprising a plurality of wires for electrically connecting the photosensitive chip to the first connection points of the substrate.

3. The image sensor according to claim 1, wherein the transparent layer is a piece of transparent glass.

4. The image sensor according to claim 1, wherein the transparent layer is transparent glue.

5. The image sensor according to claim 1, wherein the frame of the transparent layer is blurred to form the protection layer.
